(19) United States
(12) Patent Application Publication
(10) Pub. No.: US 2018/0115340 A1
(43) Pub. Date: Apr. 26, 2018

(54) RECEIVING DEVICE, TRANSMITTING DEVICE, AND SEMICONDUCTOR DEVICE AND SYSTEM USING THE SAME

(71) Applicant: SK hynix Inc., Icheon-si Gyeonggi-do (KR)

(72) Inventor: Dae Han KWON, Seoul (KR)

(73) Assignee: SK hynix Inc., Icheon-si Gyeonggi-do (KR)

(21) Appl. No.: 15/443,665

(22) Filed: Feb. 27, 2017

(30) Foreign Application Priority Data
Oct. 26, 2016 (KR) 1020160140315

(51) Int. Cl. H04B 1/401; H04B 7/08; H04B 17/364; H03K 3/356; H04L 25/03

(52) U.S. Cl. CPC H04B 1/401; H04B 7/0828; H03K 2005/00013; H03K 3/356034; H04L 25/03343; H04B 17/364

(57) ABSTRACT

A receiving device may include a buffer, a summer circuit, a first delay cell, and a second delay cell. The buffer may receive an external signal. The summer circuit may sum an output of the buffer, a first feedback signal, and a second feedback signal. The first delay cell may generate the first feedback signal by delaying an output of the summer circuit. The second delay cell may generate the second feedback signal by delaying the first feedback signal. The delay amounts of the first and second delay cells may be set based on a delay control voltage.

### CROSS-REFERENCES TO RELATED APPLICATION

The present application claims priority under 35 U.S.C. § 119(a) to Korean application number 10-2016-0140315 filed on Oct. 26, 2016, in the Korean Intellectual Property Office, which is incorporated herein by reference in its entirety.

### BACKGROUND

### 1. Technical Field

Various embodiments generally relate to a semiconductor technology, and, more particularly, to a receiving device, a transmitting device, and a semiconductor device and system using the same.

### 2. Related Art

An electronic apparatus may consist of a large number of electronic components. Among other things, a computer system may include therein many semiconductor devices, which are semiconductor based electronic components. When semiconductor devices receive and transmit electrical signals with low signal voltages and high frequencies, it is important for receiving/transmitting devices to mitigate signal distortion. For example, the receiving/transmitting devices may include a decision feedback equalizer (DFE) to compensate for signal distortion.

### SUMMARY

In an embodiment, a receiving device may include a buffer, a summer circuit, a first delay cell, and a second delay cell. The buffer may receive an external signal. The summer circuit may sum an output of the buffer, a first feedback signal, and a second feedback signal. The first delay cell may set its delay amount based on a delay control voltage, and may generate the first feedback signal by delaying an output of the summer circuit. The second delay cell may set its delay amount based on the delay control voltage, and may generate the second feedback signal by delaying the first feedback signal.

In an embodiment, a transmitting device may include a first delay cell and a driver. The first delay cell may set its delay amount based on a delay control voltage, and may delay an internal signal. The driver may drive an output node based on an output of the first delay cell.

### BRIEF DESCRIPTION OF THE DRAWINGS

FIG. 1 is a diagram illustrating an example of a system in accordance with an embodiment.

FIG. 2 is a diagram illustrating an example of a receiving device in accordance with an embodiment.

FIG. 3 is a diagram illustrating an example of a delay cell in accordance with an embodiment.

FIG. 4 is a diagram illustrating an example of a delay cell in accordance with an embodiment.

FIG. 5 is a diagram illustrating an example of a transmitting device in accordance with an embodiment.

### DETAILED DESCRIPTION

Hereinafter, a receiving device, a transmitting device, and a semiconductor device and system using the same will be described below with reference to the accompanying drawings through various examples of embodiments.

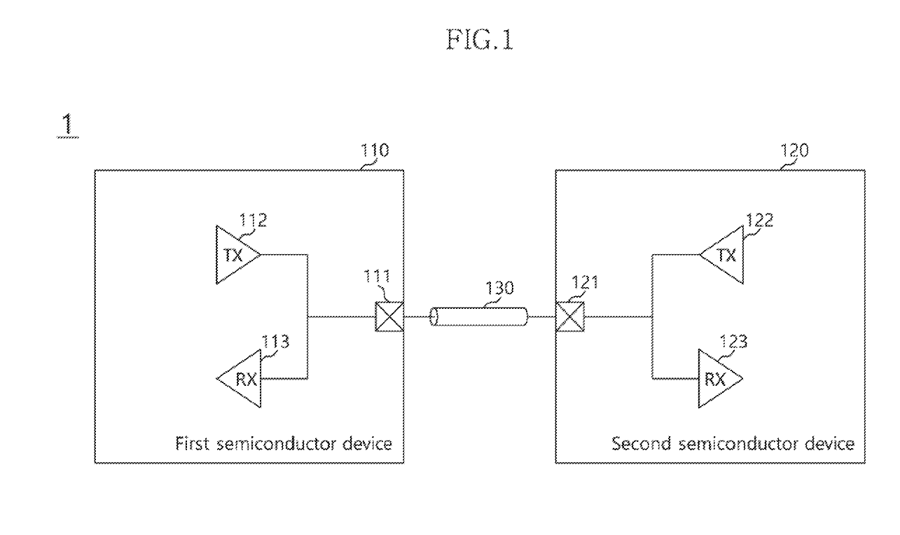

FIG. 1 is a diagram illustrating an example of a system 1 in accordance with an embodiment. In FIG. 1, the semiconductor system 1 in accordance with an embodiment may include a first semiconductor device 110 and a second semiconductor device 120. The first semiconductor device 110 and the second semiconductor device 120 may be electronic components that communicate with each other. In an embodiment, the first semiconductor device 110 may be a master device, and the second semiconductor device 120 may be a slave device that is controlled by the first semiconductor device 110. For example, the first semiconductor device 110 may be a host such as a processor. Here, examples of the processor may include a central processing unit (CPU), a graphic processing unit (GPU), a multimedia processor (MMP) or a digital signal processor (DSP). Also, the first semiconductor device 110 may be realized in the form of a system-on-chip (SOC) by integrating various processor chips having various functions, such as application processors (APs), into a single chip. The second semiconductor device 120 may be a memory, and the memory may include a volatile memory or a nonvolatile memory. Examples of the volatile memory may include a static RAM (SRAM), a dynamic RAM (DRAM) or a synchronous DRAM (SDRAM), and examples of the nonvolatile memory may include a read only memory (ROM), a programmable ROM (PROM), an electrically erasable and programmable ROM (EEPROM), an electrically programmable ROM (EPROM), a flash memory, a phase change RAM (PRAM), a magnetic RAM (MRAM), a resistive RAM (RRAM) or a ferroelectric RAM (FRAM).

The first and second semiconductor devices 110 and 120 may be coupled to each other through a signal transmission line 130. The first semiconductor device 110 may include a pad 111, and the pad 111 may be coupled to the signal transmission line 130. The second semiconductor device 120 may include a pad 121, and the pad 121 may be coupled with the signal transmission line 130. Here, the pads 111 and 121 are conductor portions of the semiconductor devices provided to make an electrical connection to an external element. The signal transmission line 130 may be a channel, a link or a bus. The first semiconductor device 110 may include a transmitting device 112 and a receiving device 113. The transmitting device 112 may generate an output signal according to an internal signal of the first semiconductor device 110, and may transmit the output signal to the second semiconductor device 120 through the signal transmission line 130. The receiving device 113 may receive a signal transmitted from the second semiconductor device 120 through the signal transmission line 130, and may generate an internal signal. Similarly, the second semiconductor device 120 may include a transmitting device 122 and a receiving device 123. The transmitting device 122 may generate an output signal according to an internal signal of the second semiconductor device 120, and may transmit the output signal to the first semiconductor device 110 through the signal transmission line 130. The receiving device 123 may receive a signal transmitted from the first semiconductor device 110 through the signal transmission line 130, and generate an internal signal.

The signal transmission line 130 may be a bus, a link or a channel capable of transmitting various signals. The signal transmission line 130 may transmit various signals such as, for example, a request, a command signal, an address signal, data and a strobe signal. The transmitting devices 112 and 122 and the receiving devices 113 and 123 may perform a certain operation to transmit/receive electrical signals without error. For example, the transmitting devices 112 and 122 and the receiving devices 113 and 123 may correct potential errors in the signal transmitted through the signal transmission line 130 or potential errors in the signal received through the signal transmission line 130. The transmitting devices 112 and 122 and the receiving devices 113 and 123 may include a decision feedback equalizer (DFE) to correct a signal transmitted or received through the signal transmission line 130.

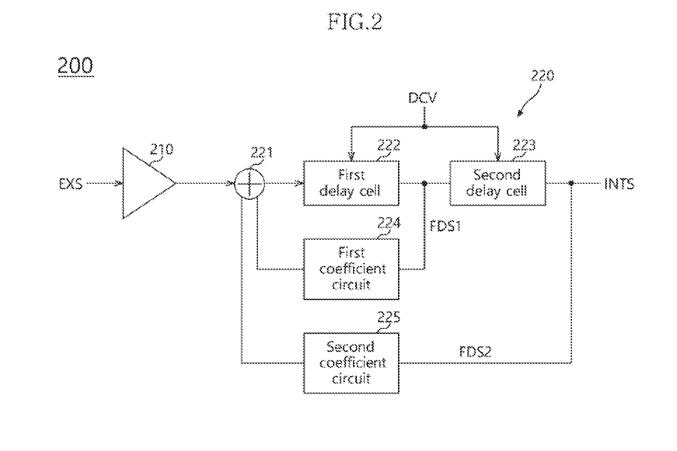

FIG. 2 is a diagram illustrating an example of a receiving device 200 in accordance with an embodiment. The concept of the receiving device 200 illustrated in FIG. 2 may be applied to the receiving devices 113 and 123 illustrated in FIG. 1. In FIG. 2, the receiving device 200 may include a buffer 210 and a decision feedback equalizer 220. The buffer 210 may buffer an external signal EXS and output an output signal. The external signal EXS may be a signal that is transmitted from an external device through the signal transmission line 130 illustrated in FIG. 1. In an embodiment, the external signal EXS may be a single-ended signal, and the buffer 210 may amplify differentially the external signal EXS. For example, the buffer 210 may amplify the difference between the external signal EXS and a reference voltage. In an embodiment, the external signal EXS may be a differential signal, and the buffer 210 may amplify the differential signal.

The decision feedback equalizer 220 may correct the output of the buffer 210 and generate an internal signal INTS. The internal signal INTS may be applied to an internal circuit of a semiconductor device that includes the receiving device 200. The decision feedback equalizer 220 may remove a post-cursor component of the signal buffered by the buffer 210, and may generate the internal signal INTS which has a precise waveform.

The decision feedback equalizer 220 may include a summer circuit 221, a first delay cell 222, and a second delay cell 223. The summer circuit 221 may sum the signal buffered by the buffer 210, a first feedback signal FDS1, and a second feedback signal FDS2.

The first delay cell 222 may delay the output of the summer circuit 221 and generate the first feedback signal FDS1. The first delay cell 222 may delay the output of the summer circuit 221 based on a delay control voltage DCV. The delay control voltage DCV may be a bias voltage generated to control a delay amount of the first delay cell 222. The delay control voltage DCV may have a voltage level that allows the first delay cell 222 to have a delay amount corresponding to a unit of delay time. The unit of delay time may be a time corresponding to, for example, one half cycle or one cycle of a clock signal. The first delay cell 222 may not receive a clock signal. The first delay cell 222 may generate the first feedback signal FDS1, instead of receiving a clock signal, by delaying the output of the summer circuit 221 by a time corresponding to a predetermined cycle of the clock signal based on the delay control voltage DCV.

The second delay cell 223 may delay the first feedback signal FDS1 and generate the second feedback signal FDS2. Similarly to the first delay cell 222, the second delay cell 223 may delay the first feedback signal FDS1 based on the delay control voltage DCV. The second delay cell 223 may have substantially the same circuit structure as the first delay cell 222. Accordingly, the second delay cell 223 may generate the second feedback signal FDS2 by delaying the first feedback signal FDS1 by a time corresponding to a predetermined cycle of the clock signal based on the delay control voltage DCV. The second feedback signal FDS2 may be provided as the internal signal INTS.

In FIG. 2, the decision feedback equalizer 220 may further include a first coefficient circuit 224 and a second coefficient circuit 225. The first coefficient circuit 224 may perform a logical or arithmetic operation on the first feedback signal FDS1, and provide a result of the operation to the summer circuit 221. The first coefficient circuit 224 may perform a logical or arithmetic operation on a first coefficient and the first feedback signal FDS1, and output a result of the operation to the summer circuit 221. For example, the first coefficient may be a weight factor associated with the first feedback signal FDS1. The first coefficient circuit 224 may multiply the first feedback signal FDS1 by the weight factor associated with the first feedback signal FDS1, and output a multiplication result to the summer circuit 221. The second coefficient circuit 225 may perform a logical or arithmetic operation on the second feedback signal FDS2, and provide a result of the operation to the summer circuit 221. The second coefficient circuit 225 may perform a logical or arithmetic operation on a second coefficient and the second feedback signal FDS2, and provide a result of the operation to the summer circuit 221. For example, the second coefficient may be a weight factor associated with the second feedback signal FDS2. The second coefficient circuit 225 may multiply the second feedback signal FDS2 by the weight factor associated with the second feedback signal FDS2, and output a multiplication result to the summer circuit 221. In FIG. 2, the summer circuit 221, the first coefficient circuit 224 and the second coefficient circuit 225 may be realized by the components of a decision feedback equalizer generally known in the art. While 2 delay cells and 2 coefficient circuits are illustrated in FIG. 2, it is to be noted that the embodiment is not limited thereto and at least 3 delay cells and at least 3 coefficient circuits may be used.

As described above, the receiving device 200 may include the first and second delay cells 222 and 223, and the amount of delay of the first and second delay cells 222 and 223 may be set based on the delay control voltage DCV. The delay cell of a general decision feedback equalizer may delay a signal input thereto by using a clock signal. Here, the clock signal may be generated by a phase-locked loop circuit or by a delay-locked loop circuit. Therefore, the clock signal should be transmitted to a receiving device through a signal transmission line. This requires more circuit area in a semiconductor device, and power consumption increases due to current consumption of the signal transmission line. Instead of using a clock signal, the receiving device 200 in accordance with an embodiment may set the amount of delay of the first and second delay cells 222 and 223 by using the delay control voltage DCV such as a bias voltage.

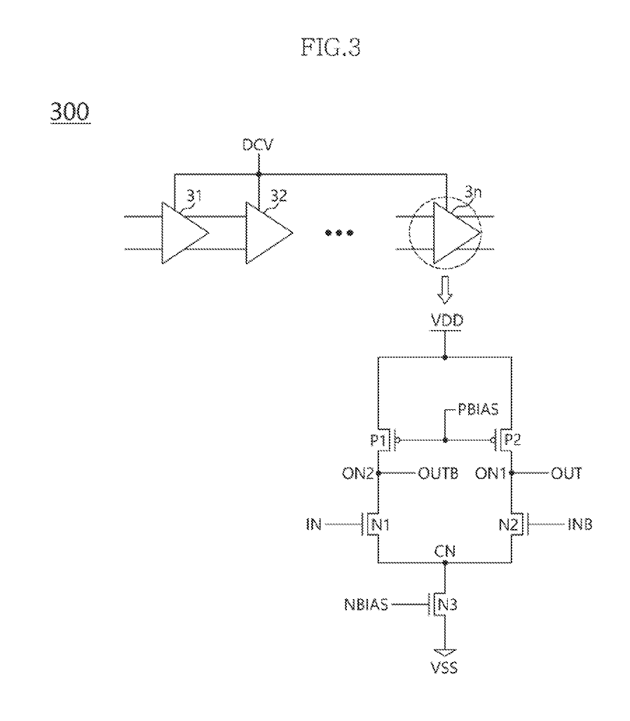

FIG. 3 is a diagram illustrating an example of a delay cell 300 in accordance with an embodiment. The concept of the delay cell 300 illustrated in FIG. 3 may be applied to the first delay cell 222 and the second delay cell 223 illustrated in FIG. 2. In FIG. 3, the delay cell 300 may include a plurality of amplifiers 31, 32, . . . and 3n (n is an integer equal to or greater than 3). Each of the plurality of amplifiers 31, 32, . . . and 3n may receive a signal through its input terminal and amplify the signal. The plurality of amplifiers 31, 32, . . . , and 3n may be coupled in series to each other, and may have the same structure as each other. The plurality of amplifiers 31, 32, . . . , and 3n may adjust the amount of delay time associated with the delay cell 300, based on the delay control voltage DCV. The delay control voltage DCV may include a first bias voltage PBIAS and a second bias voltage NBIAS. The configuration of the amplifier 3n will be described below as an example of the amplifiers 31, 32, . . . and 3n. The amplifier 3n may include a first input transistor N1, a second input transistor N2, a first transistor P1, a second transistor P2, and a third transistor N3. The first input transistor N1 may have a drain and a source which are coupled to a second output node ON2 and a common node CN, respectively, and a gate which receives an input signal IN. The second input transistor N2 may have a drain and a source which are coupled to a first output node ON1 and the common node CN, respectively, and a gate which receives a complementary signal INB of the input signal IN. The first transistor P1 may have a source and a drain which are coupled to a terminal providing a first power supply voltage VDD and the second output node ON2, respectively, and a gate which receives the first bias voltage PBIAS. The second transistor P2 may have a source and a drain which are coupled to the terminal of the first power supply voltage VDD and the first output node ON1, respectively, and a gate which receives the first bias voltage PBIAS. The third transistor N3 may have a drain and a source which are coupled to the common node CN and the terminal of a second power supply voltage VSS, respectively, and a gate which receives the second bias voltage NBIAS. The first power supply voltage VDD may be, for example, a high voltage or an external voltage, and the second power supply voltage VSS may be a low voltage or a ground voltage. The first and second transistors P1 and P2 may adjust an amount of current flowing from the terminal of the first power supply voltage VDD to the first and second output nodes ON1 and ON2, based on the first bias voltage PBIAS. The third transistor N3 may adjust an amount of current flowing from the common node CN to the terminal of the second power supply voltage VSS, based on the second bias voltage NBIAS. Therefore, the amplifier 3n may generate output signals OUT and OUTB, which are output from the first and second output nodes ON1 and ON2, according to the first and second bias voltages PBIAS and NBIAS. The other amplifiers (e.g., 31 and 32) constituting the delay cell 300 may have the same configuration as the amplifier 3n, and may generate output signals based on the first and second bias voltages PBIAS and NBIAS. Therefore, by controlling the first and second bias voltages PBIAS and NBIAS, the amount of delay produced by the delay cell 300 may be adjusted.

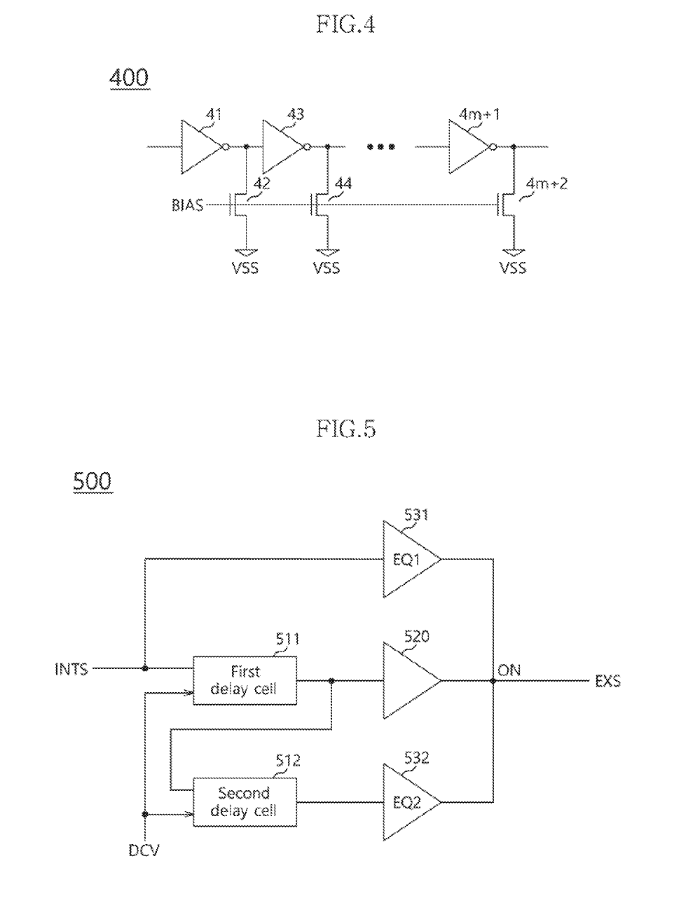

FIG. 4 is a diagram illustrating an example of a delay cell 400 in accordance with an embodiment. The concept of the delay cell 400 illustrated in FIG. 4 may be applied to the first and second delay cells 222 and 223 illustrated in FIG. 2. In FIG. 4, the amount of delay of the delay cell 400 may be set based on the delay control voltage DCV. The delay control voltage DCV may include a bias voltage BIAS. The delay cell 400 may include a plurality of inverters 41, 43, . . . , and 4m+1 (m is an integer equal to or greater than 4) and a plurality of transistors 42, 44, . . . , and 4m+2. The plurality of inverters 41, 43, . . . , and 4m+1 may be arranged sequentially and coupled in series to each other. The plurality of transistors 42, 44, . . . , and 4m+2 may be coupled to the respective output terminals of the plurality of inverters 41, 43, . . . , and 4m+1. The plurality of transistors 42, 44, . . . , and 4m+2 may couple the respective output terminals of the plurality of inverters 41, 43, . . . , and 4m+1 to the terminal of a second power supply voltage VSS based on the bias voltage BIAS. The second power supply voltage VSS may be, for example, a low voltage or a ground voltage. The plurality of transistors 42, 44, . . . , and 4m+2 may have drains and sources which are coupled to the respective output terminals of the plurality of inverters 41, 43, . . . , and 4m+1 and the terminal of the second power supply voltage VSS, respectively, and gates which receive the bias voltage BIAS. As the respective output terminals of the plurality of inverters 41, 43, . . . and 4m+1 are coupled to the terminal of the second power supply voltage VSS by the plurality of transistors 42, 44, . . . , and 4m+2, the amount of delay of the signals output through the plurality of inverters 41, 43, . . . , and 4m+1 may be adjusted. By controlling the current flowing from the output terminals of the plurality of inverters 41, 43, . . . , and 4m+1 to the terminal of the second power supply voltage VSS based on the level of the bias voltage BIAS, the amount of delay of the delay cell 400 may be adjusted.

FIG. 5 is a diagram illustrating an example of a transmitting device 500 in accordance with an embodiment. In FIG. 5, the transmitting device 500 may include a first delay cell 511 and a driver 520. The first delay cell 511 may delay an internal signal INTS and output a delayed signal of the internal signal INTS. The first delay cell 511 may receive a delay control voltage DCV. The delay control voltage DCV may be, for example, a bias voltage. The first delay cell 511 may delay the internal signal INTS based on the delay control voltage DCV and output the delayed signal of the internal signal INTS. The amount of delay of the first delay cell 511 may be set based on the delay control voltage DCV. The first delay cell 511 may delay the internal signal INTS by a unit of delay time based on the delay control voltage DCV. The unit of delay time may be a time corresponding to, for example, one half cycle or one cycle of a clock signal. The concept of the delay cells 300 and 400 illustrated in FIGS. 3 and 4 may be applied to the first delay cell 511.

The driver 520 may drive an output node ON based on the output of the first delay cell 511. An output signal EXS of the transmitting device 500 may be generated from the output node ON. The output signal EXS may be output to an external device through the pad 111 or 121 and through the signal transmission line 130 as illustrated in FIG. 1.

The transmitting 500 may further include a second delay cell 512. The second delay cell 512 may receive the output of the first delay cell 511, and may delay the output of the first delay cell 511. The second delay cell 512 may receive the delay control voltage DCV. The second delay cell 512 may delay the output of the first delay cell 511 by the unit of delay time based on the delay control voltage DCV, and may output an output signal. The second delay cell 512 may have substantially the same structure as the first delay cell 511.

The transmitting device 500 may further include a first equalizing circuit 531 and a second equalizing circuit 532. The first equalizing circuit 531 may equalize a signal being output through the output node ON based on the internal signal INTS. The second equalizing circuit 532 may equalize a signal being output through the output node ON based on the output of the second delay cell 512. For example, when the internal signal INTS is at a high level, the driver 520 may drive the output node ON after a delay time corresponding to the unit of delay time. Here, this delay is produced by the first delay cell 511. The first equalizing circuit 531 may drive the output node ON to a low level before the driver 520 drives the output node ON. The second equalizing circuit 532 receives the internal signal INTS after a delay corresponding to two units of delay time, and the second equalizing circuit 532 may drive the output node ON to the low level after the driver 520 drives the output node ON. Here, the delay corresponding to two units of delay time may be produced by the first and second delay cells 511 and 512. As the first and second equalizing circuits 531 and 532 drive the output node ON to a voltage level opposite to the internal signal INTS before and after the driver 520 drives the output node ON based on the internal signal INTS, it is possible to generate the output signal EXS precisely and stably. When the internal signal INTS is at a low level, the first and second equalizing circuits 531 and 532 may drive the output node ON to a high level before and after the driver 520 drives the output node ON. Unlike the delay cell of a general transmitting device, which sets its delay based on a clock signal, the first and second delay cells 511 and 512 of the transmitting device 500 in accordance with an embodiment may set their delay based on the delay control voltage DCV such as a bias voltage, instead of a clock signal.

While various embodiments have been described above, it will be understood to those skilled in the art that the embodiments described are examples only. Accordingly, the receiving device, the transmitting device, and the semiconductor device and system using the same described herein should not be limited based on the described embodiments.

What is claimed is:

1. A receiving device comprising:
a buffer configured to receive an external signal;
a summer circuit configured to sum an output of the buffer, a first feedback signal, and a second feedback signal;
a first delay cell configured to set its delay amount based on a delay control voltage, and generate the first feedback signal by delaying an output of the summer circuit; and
a second delay cell configured to set its delay amount based on the delay control voltage, and generate the second feedback signal by delaying the first feedback signal.

2. The receiving device according to claim 1, wherein the first delay cell comprises a plurality of amplifiers coupled in series, each amplifier receiving signals and amplifying the signals based on a first bias voltage and a second bias voltage.

3. The receiving device according to claim 1, wherein the second delay cell comprises a plurality of amplifiers coupled in series, each amplifier receiving signals and amplifying the signals based on a first bias voltage and a second bias voltage.

4. The receiving device according to claim 1, wherein the first delay cell comprises:
a plurality of inverters coupled in series; and
a plurality of transistors respectively coupled to output terminals of the plurality of inverters and configured to couple the output terminals to a terminal of a ground voltage based on a bias voltage.

5. The receiving device according to claim 1, wherein the second delay cell comprises:
a plurality of inverters coupled in series; and
a plurality of transistors respectively coupled to output terminals of the plurality of inverters and configured to couple the output terminals to a terminal of a ground voltage based on a bias voltage.

6. The receiving device according to claim 1, further comprising:
a first coefficient circuit configured to perform a logical or arithmetic operation on the first feedback signal and a first coefficient, and provide a result of the operation to the summer circuit.

7. The receiving device according to claim 1, further comprising:
a second coefficient circuit configured to perform a logical or arithmetic operation on the second feedback signal and a second coefficient, and provide a result of the operation to the summer circuit.

8. The receiving device according to claim 1, wherein the delay control voltage is a bias voltage generated to control a delay amount of the first delay cell and having a voltage level that allows the first delay cell to have a delay amount corresponding to a unit of delay time.

9. A transmitting device comprising:
a first delay cell configured to set its delay amount based on a delay control voltage, the first delay cell delaying an internal signal; and
a driver configured to drive an output node based on an output of the first delay cell.

10. The transmitting device according to claim 9, wherein the first delay cell comprises a plurality of amplifiers coupled in series, each amplifier receiving signals and amplifying the signals based on a first bias voltage and a second bias voltage.

11. The transmitting device according to claim 9, wherein the first delay cell comprises:
a plurality of inverters coupled in series; and
a plurality of transistors respectively coupled to output terminals of the plurality of inverters and configured to couple the output terminals to a terminal of a ground voltage based on a bias voltage.

12. The transmitting device according to claim 9, further comprising:
a second delay cell configured to set its delay amount based on the delay control voltage and delay an output of the first delay cell.

13. The transmitting device according to claim 12, wherein the second delay cell comprises a plurality of amplifiers coupled in series, each amplifier receiving signals and amplifying the signals based on a first bias voltage and a second bias voltage.

14. The transmitting device according to claim 12, wherein the second delay cell comprises:
a plurality of inverters coupled in series; and
a plurality of transistors respectively coupled to output terminals of the plurality of inverters and configured to couple the output terminals to a terminal of a low voltage based on a bias voltage.

15. The transmitting device according to claim 12, further comprising:
a second equalizing circuit configured to equalize a signal being output through the output node based on an output of the second delay cell.

16. The transmitting device according to claim 9, further comprising:
a first equalizing circuit configured to equalize a signal being output through the output node based on the internal signal.

17. The transmitting device according to claim 9, wherein the delay control voltage is a bias voltage generated to control a delay amount of the first delay cell and having a voltage level that allows the first delay cell to have a delay amount corresponding to a unit of delay time.
